(19) United States
(12) Patent Application Publication
(10) Pub. No.: US 2023/0365351 A1
(43) Pub. Date: Nov. 16, 2023

(54) ABNORMALITY DETECTION METHOD AND TRANSFER DEVICE

(71) Applicant: Tokyo Electron Limited, Tokyo (JP)

(72) Inventor: Toshiaki TOYOMAKI, Miyagi (JP)

(73) Assignee: Tokyo Electron Limited, Tokyo (JP)

(21) Appl. No.: 18/197,525

(22) Filed: May 15, 2023

(30) Foreign Application Priority Data
May 16, 2022 (JP) 2022-080499

(51) Int. Cl. B65G 47/91; B65G 43/00

(52) U.S. Cl. CPC B65G 47/917; B65G 43/00; B65G 2203/0283

(57) ABSTRACT

There is an abnormality detection method for a transfer device including an arm having a substrate holder to hold a substrate, an elevating mechanism to raise and lower the arm, a position detector to detect a position of the substrate holder, a suction hole formed at the substrate holder, and a pressure detector to detect a pressure of a suction passage communicating with the suction hole, the method comprising: controlling the arm to move the substrate holder to a position below the substrate; controlling the elevating mechanism to raise the arm and the substrate holder; detecting contact between the substrate and the substrate holder based on a pressure change detected by the pressure detector; detecting, by using the position detector, a position of the substrate holder at the time of detecting the contact; and detecting an abnormal state of the transfer device based on the detected position.

### CROSS-REFERENCE TO RELATED APPLICATIONS

This application claims priority to Japanese Patent Application No. 2022-080499, filed on May 16, 2022, the entire contents of which are incorporated herein by reference.

### TECHNICAL FIELD

The present disclosure relates to an abnormality detection method and a transfer device.

### BACKGROUND

Patent Document 1 discloses a substrate transfer system including an atmospheric transfer module having a first sidewall and a second sidewall opposite to the first sidewall, a load-lock module installed at the first sidewall, a load port installed at the second sidewall, and a substrate transfer robot disposed in the atmospheric transfer module.

### PRIOR ART DOCUMENTS

### Patent Documents

Patent Document 1: Japanese Laid-open Patent Publication No. 2021-141136

### SUMMARY

In one aspect, the present disclosure provides an abnormality detection method for detecting abnormality of a transfer device, and a transfer device.

In accordance with an aspect of the present disclosure, there is an abnormality detection method for a transfer device including an arm having a substrate holder configured to hold a substrate, an elevating mechanism configured to raise and lower the arm, a position detector configured to detect a position of the substrate holder, a suction hole formed at the substrate holder, and a pressure detector configured to detect a pressure of a suction passage communicating with the suction hole, the abnormality detection method comprising: controlling the arm to move the substrate holder to a position below the substrate placed on a placing part; controlling the elevating mechanism to raise the arm and the substrate holder; detecting contact between the substrate and the substrate holder based on a pressure change detected by the pressure detector; detecting, by using the position detector, a position of the substrate holder at the time of detecting the contact between the substrate and the substrate holder; and detecting an abnormal state of the transfer device based on the detected position.

### BRIEF DESCRIPTION OF THE DRAWINGS

The objects and features of the present disclosure will become apparent from the following description of embodiments, given in conjunction with the accompanying drawings, in which:

FIG. 1 shows an example of a schematic configuration of a processing system according to an embodiment;

FIG. 2 shows an example of a cross section of an aligner;

FIG. 3 shows an example of a cross section of a load-lock module;

FIG. 4 shows an example of a hardware configuration of a controller;

FIG. 5 shows an example of a schematic configuration of a pick;

FIG. 6 is a flowchart showing an example of processing performed by the controller at the time of transferring a substrate W to a pick of a transfer device;

FIGS. 7A to 7F schematically show examples of the states of the pick during processes;

FIG. 8 is a graph showing an example of an attraction pressure detected by a pressure sensor;

FIG. 9 is a graph showing an example of a pick height detected by an encoder;

FIGS. 10A and 10B show examples of postures of the pick at the time of holding a substrate; and

FIG. 11 is an example of a graph showing changes over time in a substrate attraction detection position.

### DETAILED DESCRIPTION

Hereinafter, various embodiments will be described in detail with reference to the accompanying drawings. Like reference numerals will be given to like or corresponding parts throughout the drawings.

(Processing System)

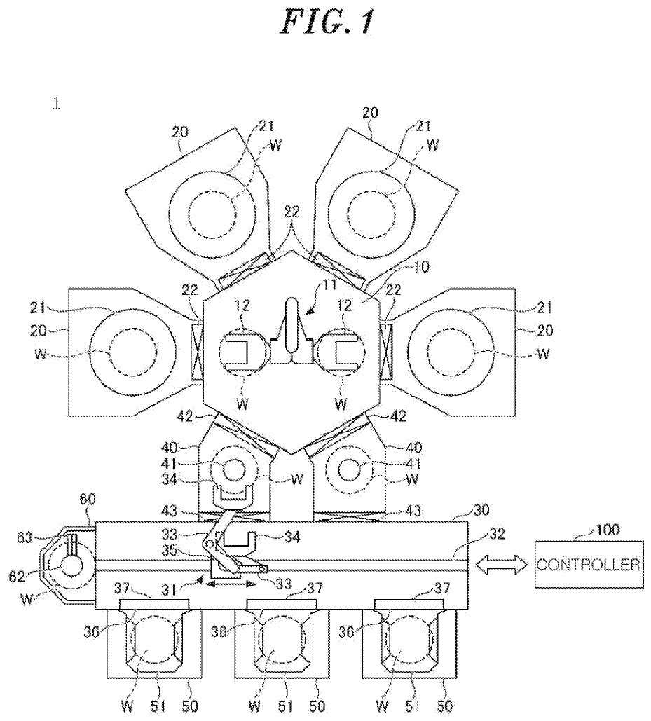

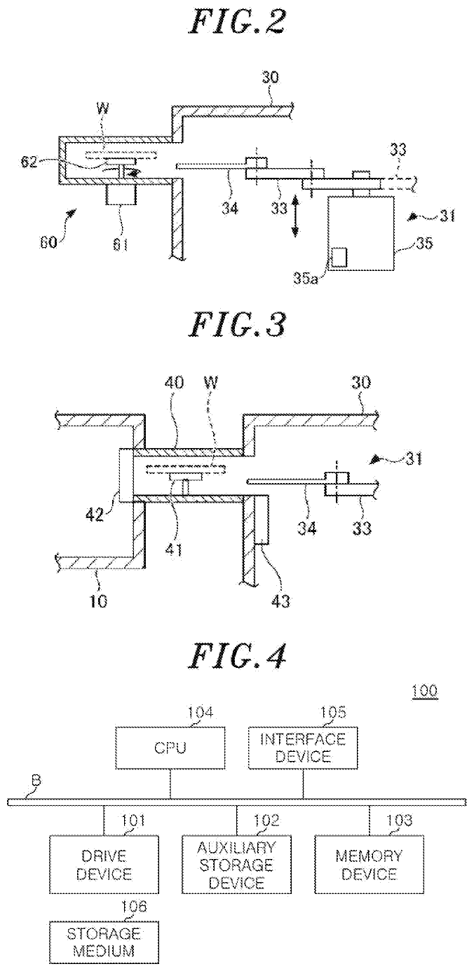

An example of a processing system 1 will be described with reference to FIGS. 1 to 4. FIG. 1 shows an example of a schematic configuration of a processing system 1 according to an embodiment. FIG. 2 shows an example of a cross section of an aligner 60. FIG. 3 shows an example of a cross section of a load-lock module 40. FIG. 4 shows an example of a hardware configuration of a controller (control part) 100.

The processing system 1 includes a transfer module 10, process modules 20, a loader module 30, load-lock modules 40, and a controller 100. In the present embodiment, four process modules 20 and two load-lock modules 40 are provided. However, the number of process modules 20 and the number of load-lock modules 40 are not limited thereto. The transfer module 10, the process modules 20, the loader module 30, and the load-lock module 40 constitute a processing apparatus.

The transfer module 10 has a substantially hexagonal shape in plan view. The transfer module 10 is configured as a vacuum chamber and has therein a transfer device 11. The transfer device 11 is configured as a multi-joint arm that can be extended/contracted, raised/lowered, and rotated to access the process modules 20 and the load-lock modules 40. The transfer device 11 has two picks (also referred to as “forks, end effectors, or substrate holders”) 12 that can be extended/contracted independently in opposite directions, and can transfer two substrates W at a time. The transfer device 11 does not necessarily have the configuration shown in FIG. 1 as long as it can transfer the substrate W such as a wafer or the like between the process modules 20 and the load-lock modules 40.

The process modules 20 are radially arranged around the transfer module 10 and connected to the transfer module 10. Each of the process modules 20 is configured as a processing chamber, and has therein a cylindrical substrate support 21 on which a substrate W is placed. In the process modules 20, various semiconductor manufacturing processes are performed on the substrate W placed on the substrate support 21. The semiconductor manufacturing processes include various processes for manufacturing semiconductors, such as film formation, etching, heat treatment, and the like. The transfer module 10 and the process modules 20 are partitioned by gate valves 22 that can be opened and closed.

The loader module 30 is disposed to face the transfer module 10. The loader module 30 is an atmospheric transfer chamber having a rectangular parallelepiped shape and maintained in an atmospheric pressure atmosphere. A transfer device 31 is disposed in the loader module 30. The transfer device 31 is slidably supported on a guide rail 32 extending along the long side of the loader module 30 at the central portion of the loader module 30. A linear motor (not shown) having, for example, an encoder is built in the guide rail 32, and the transfer device 31 moves along the guide rail 32 by driving the linear motor.

The transfer device 31 has two multi-joint arms 33 arranged in two horizontal stages. A bifurcated pick (also referred to as “fork, end effector, or substrate holder”) 34 is attached to a tip end of each of the multi-joint arms 33. The substrate W is held (placed) on each pick 34. Each of the multi-joint arms 33 can be extended/contracted in a radial direction from a center thereof and raised/lowered. The extension/contraction of the multi-joint arms 33 can be individually/independently controlled. The rotation axes of the multi-joint arms 33 are coaxially and rotatably connected to a base 35. The multi-joint arms 33 rotate integrally in a rotational direction with respect to the base 35. The guide rail 32 and the multi-joint arms 33 function as a driving mechanism for moving the pick 34. The transfer device 31 transfers the substrate W among the load-lock modules 40, transfer containers 51, and the aligner 60 that will be described later. The configuration of the transfer device 31 is not limited to that shown in FIG. 1 as long as the substrate W can be transferred among the load-lock modules 40, the transfer containers 51, and the aligner 60.

In other words, the transfer device 31 includes an arm driving mechanism (not shown) for horizontally moving the pick 34 by driving the joints of the multi-joint arm 33, an arm elevating mechanism (elevating mechanism) (not shown) for vertically moving the multi-joint arm 33 and the pick 34. The arm driving mechanism (not shown) includes a driving motor (not shown) for driving the multi-joint arm 33 and an encoder (not shown). The controller 100 receives a detection signal from the encoder of the arm driving mechanism and controls the driving motor of the arm driving mechanism. The arm elevating mechanism (not shown) includes a driving motor (not shown) for vertically moving the multi-joint arm 33 and the pick 34, and an encoder (position detector) 35a. The controller 100 receives a detection signal from the encoder 35a of the arm elevating mechanism and controls the driving motor of the arm elevating mechanism.

The two load-lock modules 40 are connected to one long side surface of the loader module 30. On the other hand, one or more loading ports 36 for introducing the substrate W are disposed at the other long side surface of the loader module 30. In the illustrated example, three loading ports 36 are disposed. An opening/closing door 37 that can be opened and closed is disposed at each of the loading ports 36. Further, load ports 50 are disposed to correspond to the loading ports 36. The transfer containers 51 for accommodating and transferring the substrates W are placed on the load ports 50. Each of the transfer container 51 may be a front opening unified pod (FOUP) that holds and accommodates a plurality of (e.g., twenty five) substrates W in multiple stages at predetermined intervals. The transfer container 51 has a container main body having an opening and accommodating the substrates W, and an opening/closing lid that closes the opening. Each of the load ports 50 is provided with a driving mechanism (not shown) for the opening/closing door 37 that can be raised/lowered and moved forward/backward to open/close the opening/closing lid of the transfer container 51.

The aligner 60 is connected to one short side surface of the loader module 30. The aligner 60 aligns the substrate W. The aligner 60 has a rotation stage 62 that is rotated by a driving motor 61 (see FIG. 2). The rotation stage 62 rotates in a state where the substrate W is placed thereon. The rotation stage 62 has a diameter smaller than the diameter of the substrate W. An optical sensor 63 for optically detecting the peripheral edge of the substrate W is disposed at the outer periphery of the rotation stage 62. The aligner 60 detects the center position of the substrate W and the direction of the notch with respect to the center of the substrate W using the optical sensor 63, and aligns the substrate W such that the center position of the substrate W and the direction of the notch with respect to the center of the substrate W become a predetermined position and a predetermined direction in the load-lock module 40.

The load-lock modules 40 are disposed between the transfer module 10 and the loader module 30. Each of the load-lock modules 40 is configured as an inner pressure variable chamber of which inner atmosphere can be switched between a vacuum state and an atmospheric pressure, and has therein a cylindrical stage 41 for placing the substrate W thereon. The stage 41 has a diameter smaller than the diameter of the substrate W. In the case of loading the substrate W from the loader module 30 into the transfer module 10, the substrate W is transferred from the loader module 30 into the load-lock module 40 maintained at an atmospheric pressure; the pressure in the load-lock module 40 is decreased; and the substrate is loaded into the transfer module 10. In the case of unloading the substrate W from the transfer module 10 into the loader module 30, the substrate W is transferred from the transfer module 10 into the load-lock module 40 maintained in a vacuum state; the pressure in the load-lock module 40 is increased to an atmospheric pressure; and the substrate W is loaded into the loader module 30. The load-lock modules 40 and the transfer module 10 are partitioned by gate valves 42 that can be opened and closed. The load-lock modules 40 and the loader module 30 are partitioned by gate valves 43 that can be opened and closed.

The controller 100 controls the operations of the respective components of the processing system 1. As shown in FIG. 4, the controller 100 is a computer including a drive device 101, an auxiliary storage device 102, a memory device 103, a CPU 104, an interface device 105, and the like that are connected to each other by a bus B. A program that realizes the processing in the controller 100 is provided by a storage medium 106 such as a CD-ROM or the like. When the storage medium 106 that stores the program is set in the drive device 101, the program is installed in the auxiliary storage device 102 from the storage medium 106 via the drive device 101. The program is not necessarily installed from the storage medium 106, and may be downloaded from another computer through a network. The auxiliary storage device 102 stores necessary data such as installed programs, recipes, and the like. The memory device 103 reads the program from the auxiliary storage device 102 and stores the program therein when there is an instruction for starting the program. The CPU 104 executes a function of the processing system 1 based on the program stored in the memory device 103. The interface device 105 is used as an interface for connection to the network.

(Pick)

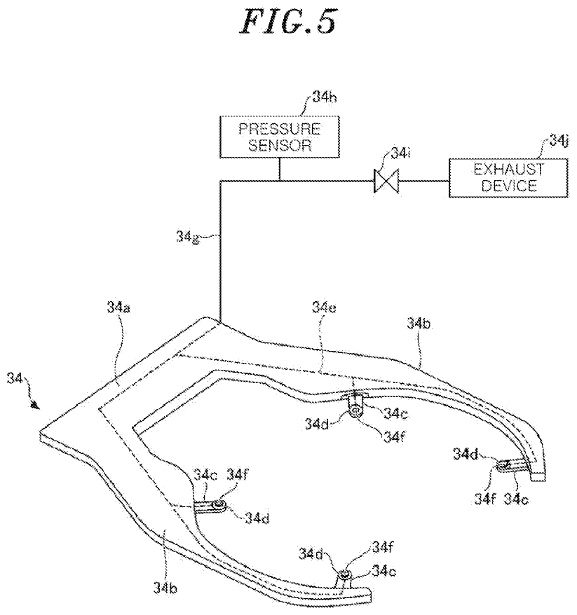

An example of the pick 34 of the transfer device 31 will be described with reference to FIG. 5. FIG. 5 shows an example of a schematic configuration of the pick 34.

The pick 34 has a base portion 34a, a tip end portion 34b, claw portions 34c, suction pads 34d, and an exhaust passage 34e. The base portion 34a is attached to the multi-joint arm 33. The tip end portion 4b extends from the base portion 34a in the forward direction of the pick 34, thereby forming an arc shape. The claw portions 34c project toward the central portion of the area (hereinafter, referred to as “wafer holding area”) surrounded by the base portion 34a and the tip end portion 34b. The four claw portions 34c are spaced apart from each other at intervals along the circumferential direction of the wafer holding area. The suction pads 34d and suction holes 34f are formed at the upper parts of the claw portions 34c. The suction pads 34d are disposed to surround the suction holes 34f. When the peripheral portion of the bottom surface of the substrate W is brought into contact with the suction pads 34d, the suction holes 34f are closed and, thus, the substrate W is attracted and held on the claw portions 34c. The exhaust passage 34e is formed in the base portion 34a and the tip end portion 34b, and forms a suction passage. One end of the exhaust passage 34e is connected to the suction holes 34f of the claw portions 34c, and the other end of the exhaust passage 34e communicates with an exhaust line 34g forming the suction passage connected to the pick 34.

A pressure sensor (pressure detector) 34h and a valve 34i are disposed in the exhaust line 34g. The pressure sensor 34h detects a pressure in the exhaust line 34g (hereinafter, also referred to as “attraction pressure”) and transmits a signal corresponding to the detected pressure to the controller 100. An exhaust device 34j is connected to the downstream side of the valve 34i of the exhaust line 34g. The exhaust device 34j includes a regulator, a vacuum pump, and the like, and adjusts the pressure in the exhaust passage 34e and the exhaust line 34g by conducting suction from the exhaust passage 34e and the exhaust line 34g. The valve 34i is controlled to be open during a period from immediately before the transfer device 31 receives the substrate W from one module to immediately after the substrate W is loaded to another module and closed during other times. Accordingly, the suction of gas from the suction holes 34f is performed during the period from immediately before the transfer device 31 holds the substrate W to immediately after the substrate W is released.

(Abnormality Detection Method)

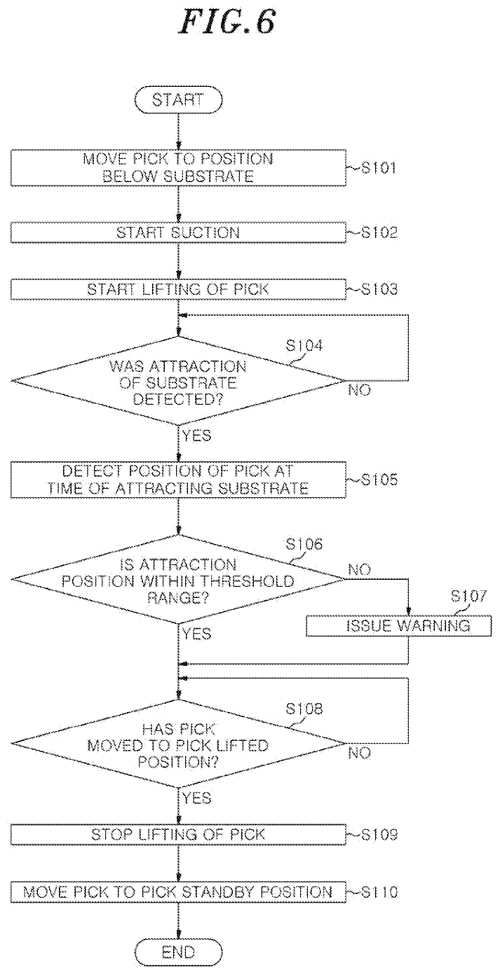

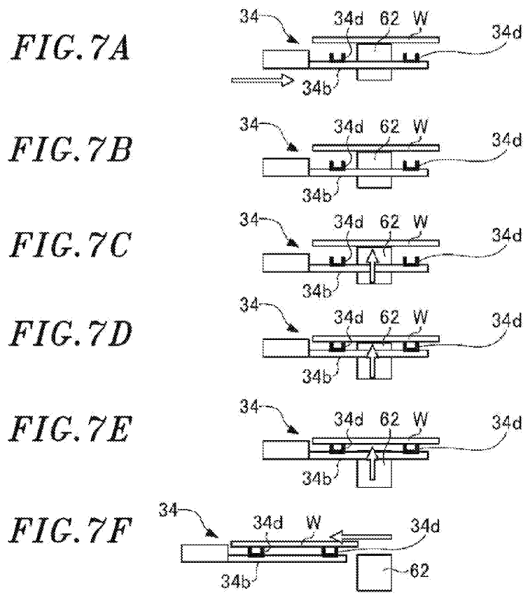

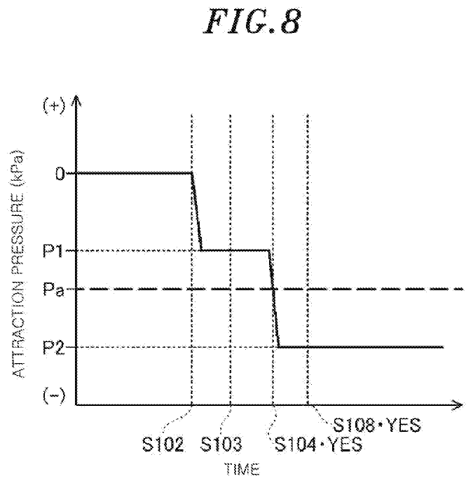

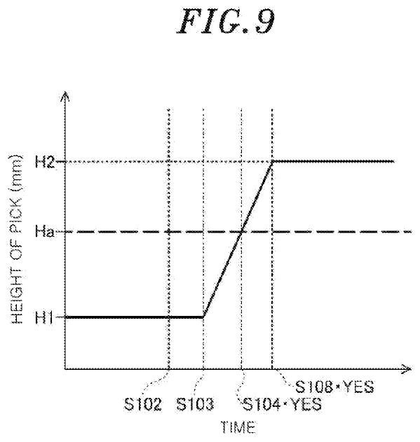

Next, an abnormality detection method for the transfer device 31 will be described with reference to FIGS. 6 to 9. FIG. 6 is a flowchart showing an example of processing performed by the controller 100 at the time of transferring the substrate W to the pick 34 of the transfer device 31. FIGS. 7A to 7F schematically show examples of the states of the pick 34 during the respective processes of FIG. 6. FIG. 8 is a graph showing an example of the attraction pressure detected by the pressure sensor 34h. FIG. 9 is a graph showing an example of the height of the pick 34 detected by the encoder 35a. In FIGS. 7A to 7F, the movements of the pick 34 are indicated by white arrows. In FIG. 8, when the pressure in the exhaust line 34g detected by the pressure sensor 34h is an atmospheric pressure, the attraction pressure is 0 (kPa); when the pressure in the exhaust line 34g detected by the pressure sensor 34h is lower than the atmospheric pressure, the attraction pressure is a negative pressure (−); and when the pressure in the exhaust line 34g detected by the pressure sensor 34h is higher than the atmospheric pressure, the attraction pressure is a positive pressure (+).

Here, an operation of transferring the substrate W placed on the rotation stage 62 of the aligner 60 to the pick 34 will be described as an example.

In step S101, the controller 100 controls the multi-joint arm 33 to move the pick 34 to a position below the substrate W (see FIG. 7A). The tip end portion 34b of the pick 34 is located below the substrate W as shown in FIG. 7A. Here, the valve 34i is closed and the attraction pressure is 0 (kPa) (see FIG. 8). The height of the pick 34 is a height H1 (see FIG. 9).

In step S102, the controller 100 starts suction from the suction holes 34f. In other words, the controller 100 opens the valve 34i and operates the exhaust device 34j to start suction from the suction holes 34f (see FIG. 7B). Accordingly, as shown in FIG. 8, the attraction pressure detected by the pressure sensor 34h is a pressure P1.

In step S103, the controller 100 starts lifting of the pick 34 (see FIG. 7C). Accordingly, as shown in FIG. 9, the pick 34 is lifted from the height H1 to a height H2 to be described later. As shown in FIG. 8, before the suction pads 34d are brought into contact with the backside of the substrate W, the attraction pressure is the pressure P1.

In step S104, the controller 100 determines whether or not the attraction (contact) of the substrate W was detected. When the attraction (contact) of the substrate W was not detected (S104: NO), the controller 100 repeats step S104. When the attraction (contact) of the substrate W was detected (S104: YES), the controller 100 proceeds to step S105.

During the lifting of the pick 34, the height of the pick 34 increases from the height H1 to the height H2 (a lifted position to be described later) as shown in FIG. 9. Here, in a state before the suction pads 34d are in contact with the backside of the substrate W (i.e., before the substrate W is attracted) as shown in FIG. 7C, the suction holes 34f are not closed, and the attraction pressure detected by the pressure sensor 34h is the pressure P1 as shown in FIG. 8. On the other hand, in a state where the suction pads 34d are in contact with the backside of the substrate W (i.e., the state in which the substrate W is attracted) as shown in FIG. 7D, the suction holes 34f are closed by the substrate W, and the attraction pressure detected by the pressure sensor 34h is a pressure P2 as shown in FIG. 8. The controller 100 determines that the substrate W has been attracted (the substrate W has been in contact with the suction pads 34d) when the attraction pressure detected by the pressure sensor 34h is lower than or equal to a reference pressure Pa (P2<Pa<P1).

In step S105, the controller 100 detects the position (height) of the pick 34 at the time of attracting the substrate. In other words, when the attraction pressure detected by the pressure sensor 34h is lower than or equal to the reference pressure Pa (S104: YES), the controller 100 detects the position (height) of the pick 34 that is obtained based on the detection signal of the encoder 35a as an attraction position Ha (see FIG. 9). Further, the controller 100 stores the detected attraction position Ha in the auxiliary storage device 102.

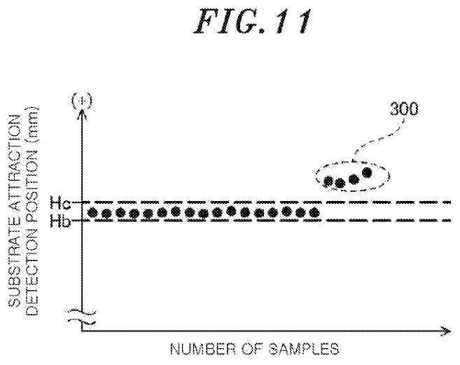

In step S106, the controller 100 determines whether or not the attraction position Ha is within a predetermined threshold range (within a range between a lower threshold value Hb and an upper threshold value Hc in FIG. 11 to be described later). If the attraction position Ha is within the predetermined threshold range (S106: YES), the controller 100 proceeds to step S108. On the other hand, if the attraction position Ha is not within the predetermined threshold range (S106: NO), the controller 100 proceeds to step S107. In step S107, the controller 100 issues warning. Then, the controller 100 proceeds to step S108.

In step S108, the controller 100 determines whether or not the position (height) of the pick 34 has moved to a predetermined pick lifted position (the height H2 shown in FIG. 9). If the pick has not moved to the pick lifted position (S108: NO), the controller 100 repeats step S108. If the pick has moved to the pick lifted position (S109: NO), the controller 100 proceeds to step S109.

In step S109, the controller 100 stops lifting of the pick 34 (see FIG. 7E).

In step S110, the controller 100 controls the multi-joint arm 33 to move the pick 34 to a pick standby position in the loader module 30. As shown in FIG. 7F, the substrate W that is vacuum-attracted by the pick 34 is unloaded from the aligner 60.

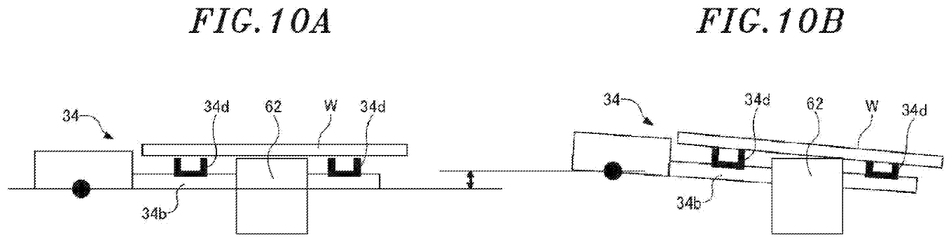

FIGS. 10A and 10B show examples of postures of the pick 34 at the time of holding the substrate. FIG. 11 is an example of a graph showing changes over time in a substrate attraction detection position. In FIG. 11, the vertical axis represents the position where the attraction of the substrate W is detected (the substrate attraction detection position, the attraction position Ha); the horizontal axis represents the number of samples in which the attraction position was detected; and black dots indicate positions where the attraction was detected.

Here, the pick 34 of the transfer device 31 is detachably attached to the multi-joint arm 33. For example, the pick 34 is fixed to the multi-joint arm 33 by a fixing member such as a bolt or the like. Here, the fixing member such as a bolt or the like may be loosened due to changes of the transfer device 31 over time, which may cause changes in the installation state of the pick 34 attached to the multi-joint arm 33.

FIG. 10A is a side view showing an example of a state in which the pick 34 is normally installed. The substrate W is placed on the rotation stage 62. The height position of the placing part (placing surface) of the rotation stage 62 is constant. When the pick 34 is normally installed, the position (height) at which the substrate W is transferred from the rotation stage 62 to the pick 34 is constant. In other words, the attraction position Ha at which the attraction of the substrate W is detected is within a predetermined threshold range (higher than or equal to the lower limit threshold value Hb and lower than or equal to the upper limit threshold value Hc).

FIG. 10B is a side view showing an example of a state in which the pick 34 is abnormally installed. Here, the pick 34 is attached to the multi-joint arm 33 with the tip end thereof tilted downward. Therefore, the position (height) of the pick 34 detected by the encoder 35a at the time of transferring the substrate W from the rotation stage 62 to the pick 34 is different from that in the state in which the pick 34 is normally installed. When the pick 34 is supported by the multi-joint arm 33 with the tip end thereof tilted downward as shown in FIG. 10B, the attraction position Ha at which the attraction of the substrate W is detected is higher than that in the state where the pick 34 is normally attached. Although not shown, when the pick 34 is supported by the multi-joint arm 33 with the tip end thereof tilted upward, the attraction position Ha at which the attraction of the substrate W is detected is lower than that in the state where the pick 34 is normally installed. This is the same when the multi-joint arm 33 has abnormality such as sagging, warpage, or the like.

As shown in steps S106 and S107 of FIG. 6, in the abnormality detection method for the transfer device 31, the controller 100 determines the state of the transfer device 31 based on the attraction position Ha. Accordingly, as shown in FIG. 11, the abnormal state (for example, an abnormal installation state of the pick 34, or the like) of the transfer device 31 can be detected when the substrate attraction detection position (the attraction position Ha) at which the attraction of the substrate W is detected is within a range 300 exceeding the predetermined threshold range Hb to Hc.

As described above, in accordance with the abnormality detection method for the transfer device 31, the abnormality of the transfer device 31 can be detected without adding an external sensor or the like. Further, when the abnormality is detected, warning can be issued. Accordingly, the maintenance of the transfer device 31 can be promoted. Hence, it is possible to prevent the pick 34 from being in unintentional contact with the substrate W or the like by operating the transfer device 31 in a state where the pick 34 is installed abnormally. Since the abnormality of the transfer device 31 can be detected during the operation of transferring the substrate W to the pick 34, a decrease in the throughput can be prevented.

Further, whenever the substrate W placed on the rotation stage 62 is transferred to the pick 34, the attraction position Ha of the substrate W may be stored, and the abnormality detection may be performed based on the changes of the plurality of attraction positions Ha over time.

The lower limit threshold Hb and the upper limit threshold Hc may be set based on the previously detected attraction position Ha. For example, the lower threshold value Hb and the upper threshold value Hc may be set with a predetermined range based on the average value of the previously detected attraction positions Ha.

In FIGS. 6 to 11, the case of performing processing at the time of receiving the substrate W placed on the rotation stage 62 of the aligner 60 while using the rotation stage 62 as the placing part has been described, but the present disclosure is not limited thereto. The present disclosure may be applied to the case of performing processing at the time of receiving the substrate W placed on the stage 41 of the load-lock module 40 while using the stage 41 as the placing part. In a configuration in which a plurality of transfer devices 31 are disposed in the loader module 30 and a placing part is provided to temporarily hold the substrate W to be transferring from the pick 34 of one transfer device 31 to the pick 34 of another transfer device 31, the present disclosure may be applied to the processing performed at the time of receiving the wafer W temporarily placed on the placing part. In other words, the processing shown in FIG. 6 may be performed at the time of transferring the substrate W from a placing part having a placing surface of which height is constant and on which the substrate W is placed to the pick 34.

Although the case where steps S106 and S107 are executed after the substrate W is attracted by the pick 34 and before the pick reaches the pick lifted position (height H2) has been described, the present disclosure is not limited thereto. For example, steps S106 and S107 may be executed after the pick has moved to the standby position.

Although the case of issuing warning when abnormality of the transfer device 31 is detected (S106: NO) has been described, the present disclosure is not limited thereto. The operation of the transfer device 31 may be stopped.

While the embodiment of the processing system 1 has been described, the present disclosure is not limited to the above-described embodiment, and various changes and improvements may be made without departing from the scope of the appended claims and the gist thereof.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. An abnormality detection method for a transfer device including an arm having a substrate holder configured to hold a substrate, an elevating mechanism configured to raise and lower the arm, a position detector configured to detect a position of the substrate holder, a suction hole formed at the substrate holder, and a pressure detector configured to detect a pressure of a suction passage communicating with the suction hole, the abnormality detection method comprising:
controlling the arm to move the substrate holder to a position below the substrate placed on a placing part;
controlling the elevating mechanism to raise the arm and the substrate holder;
detecting contact between the substrate and the substrate holder based on a pressure change detected by the pressure detector;
detecting, by using the position detector, a position of the substrate holder at the time of detecting the contact between the substrate and the substrate holder; and
detecting an abnormal state of the transfer device based on the detected position.

2. The abnormality detection method of claim 1, wherein when the detected position is outside a predetermined threshold range, the state of the transfer device is determined to be abnormal.

3. The abnormality detection method of claim 2, wherein the predetermined threshold range is set based on previously detected positions.

4. The abnormality detection method of claim 1, wherein in said detecting the contact between the substrate and the substrate holder, the contact between the substrate and the substrate holder is detected when the pressure detected by the pressure detector is lower than or equal to a predetermined reference pressure.

5. The abnormality detection method of claim 1, wherein the transfer device transfers a substrate in an atmospheric pressure atmosphere.

6. A transfer device comprising:
an arm having a substrate holder configured to hold a substrate;
an elevating mechanism configured to raise and lower the arm;
a position detector configured to detect a position of the substrate holder;
a suction hole and a suction passage formed in the substrate holder;
a pressure detector configured to detect a pressure in the suction path; and
a controller,
wherein the controller is configured to control the arm to move the substrate holder to a position below the substrate placed on a placing part, control the elevating mechanism to raise the arm and the substrate holder, detect contact between the substrate and the substrate holder based on a pressure change detected by the pressure detector, detect a position of the substrate holder at the time of detecting the contact between the substrate and the substrate holder by using the position detector, and detect an abnormal state of the transfer device based on the detected position.

7. The transfer device of claim 6, wherein when the detected position is outside a predetermined threshold range, a state of the transfer device is determined to be abnormal.

8. The transfer device of claim 7, wherein the predetermined threshold range is set based on previously detected positions.

9. The transfer device of claim 6, wherein the contact between the substrate and the substrate holder is detected when the pressure detected by the pressure detector is lower than or equal to a predetermined reference pressure.

10. The transfer device of claim 6, wherein the transfer device transfers a substrate in an atmospheric pressure atmosphere.
